(19) United States
(12) Patent Application Publication
(10) Pub. No.: US 2023/0021179 A1
(43) Pub. Date: Jan. 19, 2023

(54) SEMICONDUCTOR DEVICE WITH A MULTILAYER PACKAGE SUBSTRATE

(71) Applicant: TEXAS INSTRUMENTS INCORPORATED, Dallas, TX (US)

(72) Inventors: Yiqi Tang, Allen, TX (US); Rajen Manicon Murugan, Dallas, TX (US); Chittranjan Mohan Gupta, Richardson, TX (US); Jie Chen, Plano, TX (US)

(21) Appl. No.: 17/379,549

(22) Filed: Jul. 19, 2021

(51) Int. Cl. H01L 49/02; H01F 17/00; H05K 3/46; H05K 1/11; H02M 3/158

(52) U.S. Cl. CPC H01L 28/10; H01F 17/0013; H05K 3/4644; H05K 1/113; H02M 3/158; H01F 2017/0026; H01F 2017/0073

(57) ABSTRACT

A semiconductor device includes a die having an input port and an output port. The semiconductor device also includes a multilayer package substrate with pads on a surface of the multilayer package substrate configured to be coupled to circuit components of a printed circuit board. The multilayer package substrate also includes a passive filter comprising an input port and an output port, and a planar inductor. The planar inductor is coupled to a given pad of the pads of the multilayer package substrate with a first via of the multilayer package substrate and to the input port of the die with a second via of the multilayer package substrate. The planar inductor extends parallel to the surface of the multilayer package substrate.

### CROSS-REFERENCE TO RELATED APPLICATION

This application claims the benefit of priority to U.S. Provisional Application No. 63/056,322 filed on 24 Jul. 2020, the entirety of which is incorporated herein by reference.

### TECHNICAL FIELD

This disclosure relates to semiconductor devices. More particularly, this disclosure relates to a semiconductor device that includes a multilayer package substrate.

### BACKGROUND

An increasing development of electronics demands more and more high-performance inductors. In analog circuits the footprint of coils needed to implement inductors restrict the electrical characteristics of the designs. Modern RF designs like filters, oscillators, transceivers, or amplifiers require high-factors at high frequencies. Additionally, the chip size is mainly determined by the extensive layout of the inductors, which raises the costs for production.

In electrical engineering, power conversion is the process of converting electric energy from one form to another. A power converter is an electrical device that can convert electrical energy. Some power converters convert alternating current (AC) into direct current (DC). Other power converters, namely a DC-to-DC power converter converts a source of DC from one voltage level to another voltage level.

A buck converter, also referred to as a step-down converter, is a DC-to-DC converter that steps down voltage (while stepping up current) from an input port (supply) to an output port (coupled to a load). A boost converter, also referred to as a step-up converter, is a DC-to-DC power converter that steps up voltage (while stepping down current) from an input port (supply) to an output port (coupled to a load). A buck converter and a boost converter are both forms of a switched mode power supply.

### SUMMARY

A first example relates to a semiconductor device that includes a die with an input port and an output port. The semiconductor device also includes a multilayer package substrate with pads on a surface of the multilayer package substrate configured to be coupled to circuit components of a printed circuit board (PCB). The multilayer package substrate also includes a passive filter with an input port and an output port, and a planar inductor. The planar inductor is coupled to a given pad of the pads of the multilayer package substrate with a first via of the multilayer package substrate and to the input port of the die with a second via of the multilayer package substrate. The planar inductor extends parallel to the surface of the multilayer package substrate.

A second example relates to a method for forming a semiconductor device. The method includes forming a multilayer package substrate that include pads on a surface for connecting the semiconductor device to a printed circuit board. The multilayer package substrate also includes a passive filter with a planar inductor coupled to a first pad of the pads of the multilayer package substrate with a first via and to an output port of the multilayer package substrate with a second via. The planar inductor extends in parallel to the surface of the multilayer package substrate. The method also includes mounting the die to the multilayer package substrate. The die includes an input port coupled to the output port of the multilayer package substrate and an output port coupled to a second pad of the pads of the multilayer package substrate.

### BRIEF DESCRIPTION OF THE DRAWINGS

FIG. 1 illustrates a diagram of an example of a semiconductor device with a multilayer package substrate that has an integrated passive filter that is mounted on a printed circuit board (PCB).

FIG. 2A illustrates a first view of a three-dimensional (3D) model of an example multilayer package substrate that includes a spiral inductor.

FIG. 2B illustrates a second view of the 3D model of the multilayer package substrate illustrated in FIG. 2A.

FIG. 2C illustrates a third view of the 3D model of the multilayer package substrate illustrated in FIG. 2A.

FIG. 3A illustrates a first view of a 3D model of an example multilayer package substrate that includes two spiral inductors.

FIG. 3B illustrates a second view of the 3D model of the multilayer package substrate illustrated in FIG. 3A.

FIG. 3C illustrates a third view of the 3D model of the multilayer package substrate illustrated in FIG. 3A.

FIG. 4 illustrates a circuit diagram of an example of a semiconductor device with a multilayer package substrate that includes a passive filter mounted on a PCB.

FIG. 5 illustrates a graph that plots a gain as a function of frequency of a buck converter.

FIG. 6 illustrates another graph that plots a gain as a function of frequency of a buck converter.

FIG. 7 illustrates a first stage of a method for forming a multilayer package substrate.

FIG. 8 illustrates a second stage of a method for forming the multilayer package substrate.

FIG. 9 illustrates a third stage of a method for forming the multilayer package substrate.

FIG. 10 illustrates a fourth stage of a method for forming the multilayer package substrate.

FIG. 11 illustrates a fifth stage of a method for forming the multilayer package substrate.

FIG. 12 illustrates a sixth stage of a method for forming the multilayer package substrate.

FIG. 13 illustrates a seventh stage of a method for forming the multilayer package substrate.

FIG. 14 illustrates an eighth stage of a method for forming the multilayer package substrate.

FIG. 15 illustrates a ninth stage of a method for forming the multilayer package substrate.

FIG. 16 illustrates a first stage of packaging to form a semiconductor device.

FIG. 17 illustrates a second stage of packaging to form the semiconductor device.

FIG. 18 illustrates a third stage of packaging to form the semiconductor device.

FIG. 19 illustrates a flowchart of an example method for forming a semiconductor device.

### DETAILED DESCRIPTION

This description relates to a semiconductor device, such as an IC package that includes a multilayer package substrate with an inductor integrated therein. Additionally, in some examples, the multilayer package substrate also includes a capacitor integrated within the multilayer package substrate. The inductor is a planar inductor formed of a trace on a particular level of the multilayer package substrate. In some examples, the planar inductor is a spiral inductor (e.g., an oval spiral or a circular spiral), and in other examples, other shapes are employable. In some examples, the multilayer package substrate has a single inductor, and in other examples, the multilayer package substrate has two inductors. In some examples, the capacitor integrated with the multilayer package substrate is a surface mount technology (SMT) capacitor. In other examples, the capacitor is formed with plates situated on spaced apart layers of the multilayer package substrate.

A die is mounted on the multilayer package substrate. In some examples, the die includes a power converter module, such as a buck converter or a boost converter. Accordingly, in some examples, the inductor and the capacitor of the multilayer package substrate is employable as a passive filter for the power converter module.

The semiconductor device is mountable on a printed circuit board (PCB). In the examples provided, the PCB includes a bulk filter formed of discrete circuit components, such as surface SMT components. In some examples, the bulk filter mounted on the PCB is also a filter for the power converter module of the semiconductor device and is coupled in series with the passive filter. More particularly, the bulk filter mounted on the PCB is a first section filter of a two section input filter for the power converter module. Additionally, the passive filter integrated with the multilayer package substrate is a second section filter for the two section input filter for the power converter module. Inclusion of a two section input filter for the power converter module improves converter performance, with respect to noise rejection, loop gain, etc.

Employment of the semiconductor device obviates the need for mounting the second section filter of the two section input filter for the power converter module on the PCB. Instead, the inductor and the capacitor forming the second section filter are integrated within the multilayer package substrate. Accordingly, the power converter module achieves the benefits of inclusion of the second section filter (e.g., improved noise rejection at certain frequency ranges) without increasing a footprint size or increasing the cost to the semiconductor device.

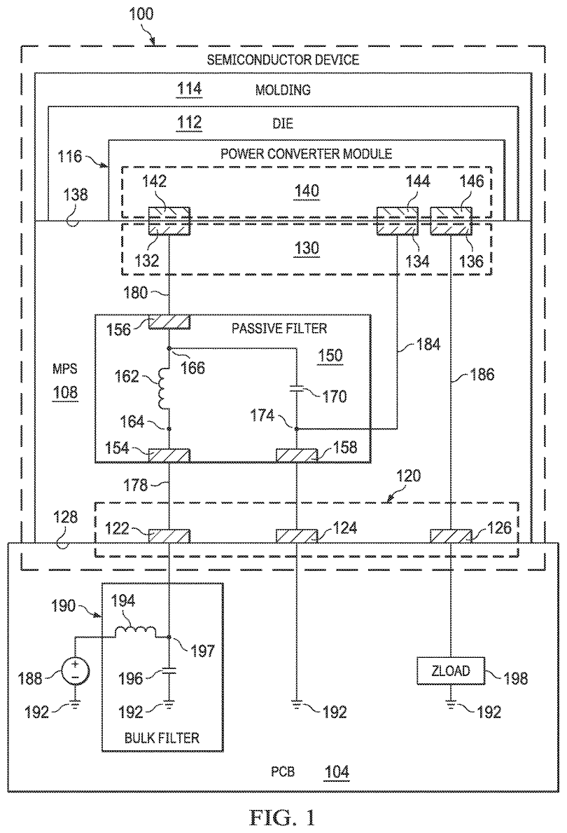

FIG. 1 illustrates a diagram of an example of a semiconductor device 100 mounted on a printed circuit board (PCB) 104. The semiconductor device 100 implemented as an integrated circuit (IC) package. The semiconductor device 100 includes a multilayer package substrate 108 (labeled MPS in the FIGS.), such as a multilayer package substrate quad flat no leads (QFN). Moreover, a die 112 of the semiconductor device 100 is mounted on the multilayer package substrate 108 and encapsulated in a molding 114 (e.g., plastic). In the examples provided, the multilayer package substrate 108 is employed as a type of connection assembly for connecting the die 112 to the PCB 104. In other examples, other types of connection assemblies are employable in place of the multilayer package substrate 108.

The die 112 includes modules for implementing electrical operations. In some examples, the die 112 includes a power converter module 116. As one example, the power converter module 116 is a DC-to-DC converter, such as a buck converter (a step-down converter) or a boost converter (a step-up converter). In other examples, the power converter module 116 is an AC-to-DC converter. In still other examples, the power converter module 116 is omitted. For the examples provided, it is presumed that the power converter module 116 is a DC-to-DC converter.

The multilayer package substrate 108 includes pads 120 for connecting the semiconductor device 100 to the PCB 104. More particularly, in the illustrated example, there is a first pad 122, a second pad 124 and a third pad 126, but in other examples, there are more pads 120. The pads 120 are arranged on a first surface 128 (e.g., a planar surface or bottom) of the multilayer package substrate 108. The multilayer package substrate 108 also includes ports 130 for coupling the multilayer package substrate 108 to the die 112. In the example illustrated, the multilayer package substrate 108 includes a first port 132, a second port 134 and a third port 136, but in other examples, the multilayer package substrate 108 includes additional ports. The ports 130 are coupled to corresponding ports 140 of the die 112, such that in the example illustrated, the die 112 includes a first port 142, a second port 144 and a third port 146. The ports 130 of the multilayer package substrate 108 are arranged on a second surface 138 (e.g., a planar surface and/or top surface) of the multilayer package substrate 108. The first surface 128 of the multilayer package substrate 108 opposes the second surface 138 of the multilayer package substrate 108.

In the example illustrated, it is presumed that the first port 142 of the die 112 is an input port of the power converter module 116. Thus, the first port 132 of the ports 130 of the multilayer package substrate 108 is an output port of the multilayer package substrate. Similarly, the third port 146 of the die 112 is an output port of the power converter module 116 and the third port 136 of the multilayer package substrate is an input port. Moreover, the second port 134 of the ports 130 of the multilayer package substrate 108 and the second port 144 of the die 112 are neutral ports (e.g., ground ports) configured to be coupled to an electrically neutral node.

The multilayer package substrate 108 includes a passive filter 150 that has discrete components formed on an interior layer (or multiple interior layers) of the multilayer package substrate 108. The passive filter 150 includes an input port 154, an output port 156 and a neutral port 158. Additionally, the passive filter 150 includes a planar inductor 162 coupled to a first node 164 and a second node 166 of the passive filter 150. The first node 164 of the passive filter 150 is coupled to the input port 154 of the passive filter 150 and the second node 166 of the passive filter 150 is coupled to the output port 156 of the passive filter 150.

The planar inductor 162 is formed on an interior layer of the multilayer package substrate 108. Thus, the planar inductor 162 of the passive filter 150 is spaced apart from a layer of the multilayer package substrate 108 that includes the pads 120. Moreover, in some examples, the layer of the multilayer package substrate 108 that includes the planar inductor 162 is also spaced apart from a layer of the multilayer package substrate 108 that includes the ports 130. The planar inductor 162 is formed with a planar trace on a particular level of the multilevel package substrate that extends in a direction parallel to the first surface 128 of the multilayer package substrate 108. In some examples, the planar inductor 162 is a spiral inductor, such that the trace forming the planar inductor has a spiral shape (a circular spiral, a square spiral, an oval spiral or other type of symmetric spiral). In some examples, the planar inductor 162 is representative of two planar inductors that have about equal inductance. Unless otherwise stated, in this description, ‘about’ preceding a value means +/−10 percent of the stated value. In other examples, the planar inductor 162 is representative of a single planar inductor.

In some examples, the passive filter 150 also includes a capacitor 170. The capacitor 170 is coupled to a third node 174 of the passive filter 150 and to the second node 166 of the passive filter 150. In some examples, the capacitor 170 is formed with a surface mount technology (SMT) capacitor, or multiple SMT capacitors mounted on the multilayer package substrate 108. In other examples, the capacitor 170 is formed of spaced apart plates on different layers of the multilayer package substrate 108. In such a situation, the plates extend in a direction parallel to the first surface 128 of the multilayer package substrate 108. Additionally, in some examples, the capacitor 170 is representative of multiple capacitors 170, and in other examples the capacitor 170 is representative of a single capacitor.

The input port 154 and the first node 164 of the passive filter 150 is coupled to the multilayer package substrate 108 with a first via 178. Also, the second node 166 and the output port 156 of the passive filter 150 is coupled to the first port 132 of the multilayer package substrate 108 with a second via 180. Further, the third node 174 of the passive filter 150 is coupled to the neutral port 158 of the passive filter 150, the second port 134 of the multilayer package substrate 108 and the second pad 124 of the multilayer package substrate 108. More particularly, the third node 174 of the passive filter 150 is coupled to the second port 134 with a third via 184. Further the third port 136 of the multilayer package substrate 108 is coupled to the third pad 126 of the multilayer package substrate 108 with a fourth via 186.

In some examples, the PCB 104 includes a voltage source 188 with a positive terminal coupled to a bulk filter 190 and a negative terminal coupled to a electrically neutral node 192 (e.g., ground or virtual ground). The bulk filter 190 is coupled in series with the passive filter 150. In the example illustrated, the bulk filter 190 is formed of an inductor 194 and a capacitor 196, but in other examples, other filtering schemes that implement other arrangements are possible. Additionally, in some examples, the bulk filter 190 is an active filter, whereby the inductor 194 is omitted. In some examples, the capacitor 196 is coupled to the electrically neutral node 192 and to a node 197 of the PCB 104. In such a situation, the inductor 194 is coupled to the positive terminal of the voltage source 188 and to the node 197 of the PCB 104.

The second pad 124 is coupled to the electrically neutral node 192. Additionally, the third pad 126 is configured to be coupled to a load 198 (labeled “ZLOAD”). The load 198 is coupled to the electrically neutral node 192. In some examples, the load 198 is representative of an impedance load that includes a resistive component, an inductive component and/or a capacitive component.

In operation of the power converter module 116, power flows from the voltage source 188 through the bulk filter 190 and through the passive filter 150. The bulk filter 190 operates as a first section filter of a two section input filter for the power converter module 116, and the passive filter 150 operates as a second section filter of the two section input filter of the power converter module 116. Thus, power flows from the passive filter 150 to the power converter module 116. Internally, the power converter module 116 includes control signals controlling a switching state of a high side and a low side transistor to provide power to the load 198. The power provided to the load 198 is based on power flowing out of the passive filter 150 and to the power converter module 116. Thus, noise induced by the voltage source 188 can induce noise at the load 198. However, the two section input filter implemented by the bulk filter 190 and the passive filter 150 curtails this noise, which in turn curtails noise at the load 198.

By employment of the semiconductor device 100, a passive filter that includes an inductor, namely the planar inductor 162 is integrated with the semiconductor device 100 itself. More specifically, the planar inductor 162 is formed on a layer of the multilayer package substrate 108, and in some examples, the multilayer package substrate 108 also includes a capacitor formed on other layers of the multilayer package substrate 108. Thus, the semiconductor device 100 implements the passive filter 150 that is included in addition to the bulk filter 190. In this manner, the multilayer package substrate 108 and the PCB 104 operate in concert to provide a two section input filter for the power converter module 116. Furthermore, in examples where the bulk filter 190 is omitted, the passive filter 150 still provides filtering operations.

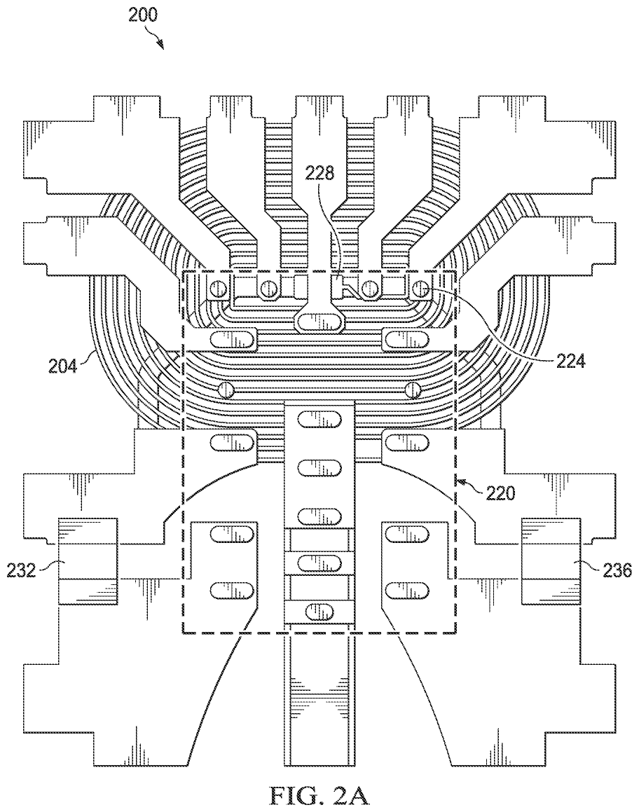

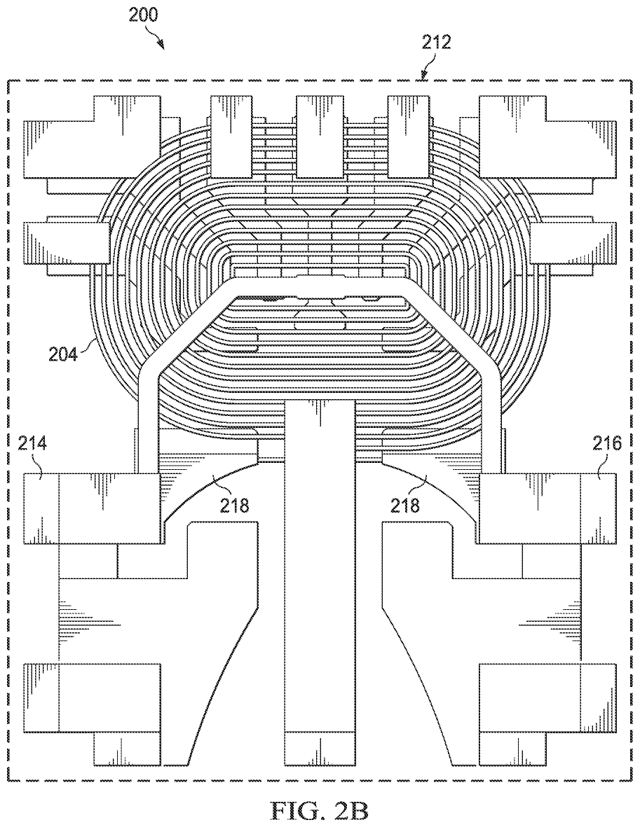

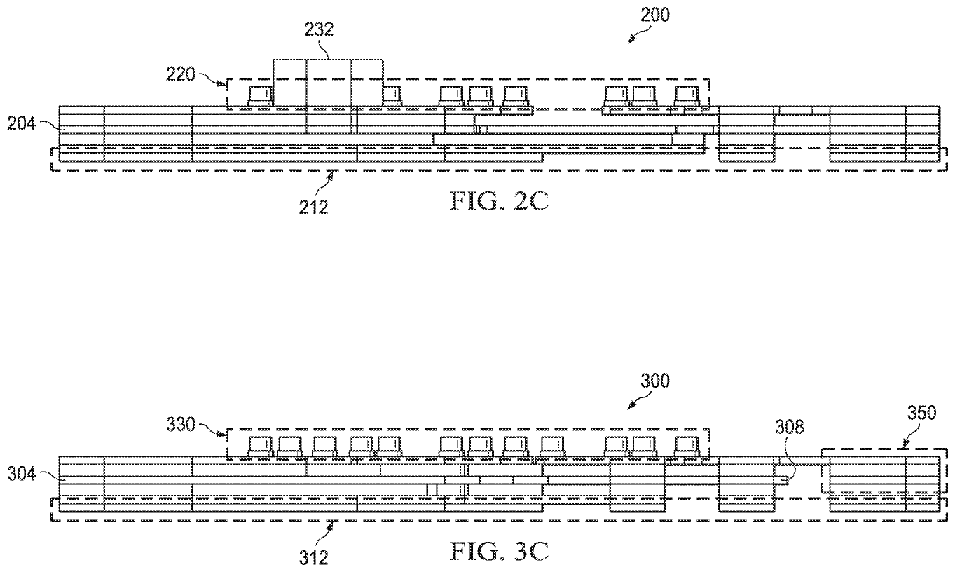

FIGS. 2A, 2B and 2C illustrate an example three-dimensional (3D) model of a multilayer package substrate 200 for a semiconductor device, wherein a die and molding (packaging) have been made transparent to illustrate details of the multilayer package substrate 200. FIG. 2A illustrates a view of the multilayer package substrate 200 from a first side (e.g., a top view). FIG. 2B illustrates a view of the multilayer package substrate 200 from a second side (e.g., a bottom view). FIG. 2C illustrates a view of the multilayer package substrate 200 from a third side (e.g., a side view). Thus, FIGS. 2A, 2B and 2C employ the same reference numbers to denote the same structure.

The multilayer package substrate 200 has a symmetrical shape, and includes a spiral inductor 204 (e.g., a planar inductor) that is employable to implement the planar inductor 162 of FIG. 1. The spiral inductor 204 is formed of a trace that has a spiraling oval shape and is formed on an interior layer of the multilayer package substrate 200. A first layer (e.g., a bottom layer, in one perspective) of the multilayer package substrate 200 includes pads 212 configured to be coupled to a PCB. In other examples, the spiral inductor 204 has a non-spiral shape. The pads 212 include a first pad 214 and a second pad 216 that are coupled to a first node 218 of the spiral inductor 204 through a via. Accordingly, the first pad 214 and the second pad 216, coupled together at the first node 218 of the spiral inductor 204 are employable to implement the first pad 122 of the multilayer package substrate 108 of FIG. 1. The spiral inductor 204 is formed such that the spiral inductor 204 extends parallel to a surface of the resultant semiconductor device that includes the pads 212 (e.g., a bottom surface).

Additionally, a second layer (e.g., a top layer, in one perspective) of the multilayer package substrate 200 includes ports 220. The ports 220 are configured to be coupled to a die, such as the die 112 of FIG. 1. An output port 224 of the ports 220 is coupled to a second node 228 of the spiral inductor 204 through a via. Accordingly, the output port 224 is employable to implement the first port 132 of FIG. 1. Additionally, an electrical path extending from the first pad 214 and the second pad 216 (that are coupled together at the first node 218 of the spiral inductor 204) through the spiral inductor 204 and to the output port 224 is established. Accordingly, the spiral inductor 204 is employable to implement the planar inductor 162 for the passive filter 150 of FIG. 1.

The spiral inductor 204 is formed on a layer spaced apart from the layer that includes the pads 212 and the ports 220. Stated differently, the spiral inductor 204 is formed on an interior layer of the multilayer package substrate 200.

The multilayer package substrate 200 also includes a first capacitor 232 and a second capacitor 236 mounted on plates of the multilayer package substrate 200. The first capacitor 232 and the second capacitor 236 are implemented as surface mount technology (SMT) capacitors. In the example illustrated, the first capacitor 232 and the second capacitor 236 provide the capacitor 170 of FIG. 1. In other examples, plates (not shown) of a capacitor are also formed on the multilayer package substrate 200 to provide the capacitor 170 of FIG. 1.

In some examples, the spiral inductor 204 has an inductance of about 180-350 nanohenries (nH), such as 309.22 nH, in one example. Additionally, the spiral inductor 204 has a parasitic resistance of about 1227.4 milliohms (mΩ) in one example. Furthermore, in such a situation, the first capacitor 232 and the second capacitor 236 have a combined capacitance of about 0.3-0.8 picofarads (pF), such as about 0.69 pF in one example. Moreover, the spiral inductor 204 has a quality factor (Q) at 10 megahertz (MHz) of about 80.0.

By employment of the multilayer package substrate 200, a relatively large inductor, namely the spiral inductor 204 is provided in a relatively small footprint, namely the footprint of the corresponding semiconductor device (e.g., the semiconductor device 100 of FIG. 1). Thus, the spiral inductor 204, the first capacitor 232 and the second capacitor 236 are employable in a passive filter (e.g., the passive filter 150 of FIG. 1), such as in a second section filter of a two section input filter for a power converter.

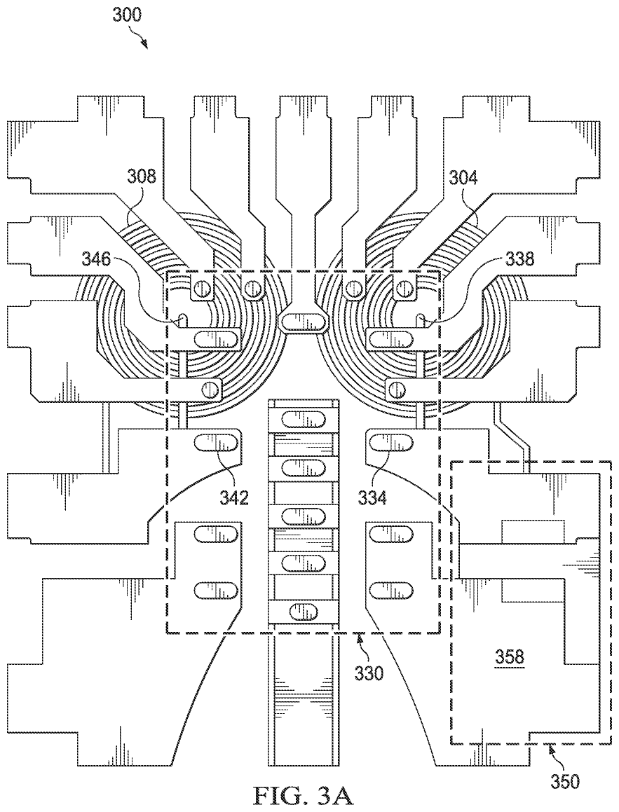

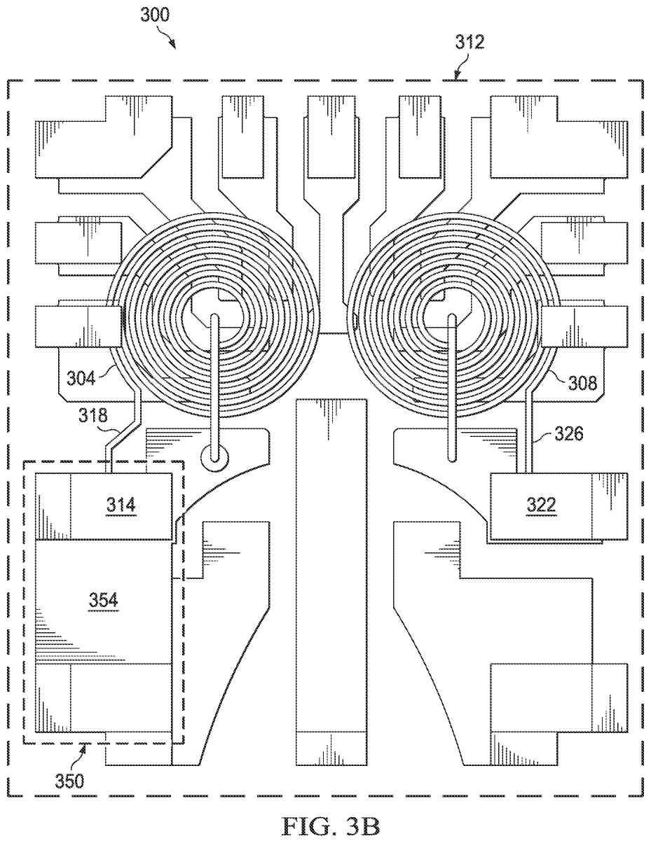

FIGS. 3A, 3B and 3C illustrate another 3D model of a multilayer package substrate 300 for a semiconductor device, wherein a die and molding (packaging) have been made transparent to illustrate details of the multilayer package substrate 300. FIG. 3A illustrates a view of the multilayer package substrate 300 from a first side (e.g., a top view). FIG. 3B illustrates a view of the multilayer package substrate 300 from a second side (e.g., a bottom view). FIG. 3C illustrates a view of the multilayer package substrate 300 from a third side (e.g., a side view). Thus, FIGS. 3A, 3B and 3C employ the same reference numbers to denote the same structure.

The multilayer package substrate 300 has a symmetrical shape, and includes a first spiral inductor 304 (a first planar inductor) and a second spiral inductor 308 (a second planar inductor) that are employable to implement the planar inductor 162 of FIG. 1. In other examples, the first spiral inductor 304 and the second spiral inductor 308 are implemented as planar inductors with non-spiral shapes. The first spiral inductor 304 and the second spiral inductor 308 are formed of respective traces that have a spiraling circle shape and are formed on an interior layer of the multilayer package substrate 300. In some examples, the first spiral inductor 304 and the second spiral inductor 308 have about equal inductance. The first spiral inductor 304 and the second spiral inductor 308 are spaced apart from each other. A first layer (e.g., a bottom layer, in one perspective) of the multilayer package substrate 300 includes pads 312 configured to be coupled to a PCB. The pads 312 include a first pad 314 coupled to a first node 318 of the first spiral inductor 304 with a via. The pads 312 also include a second pad 322 coupled to a first node 326 of the second spiral inductor 308 with a via. In some examples, the first pad 314 and the second pad 322 are coupled to a common node (e.g., a positive voltage source), such that the first node 318 of the first spiral inductor 304 and the first node 326 of the second spiral inductor 308 are also coupled together. Accordingly, in this example, the first pad 314 and the second pad 322 are employable to implement the first pad 122 of the multilayer package substrate 108 of FIG. 1. In other examples, the first pad 314 and the second pad 322 are configured to be coupled to different nodes on the PCB. Additionally, the first spiral inductor 304 and the second spiral inductor 308 are formed such that the first spiral inductor 304 and the second spiral inductor 308 extend parallel to a surface of the resultant semiconductor device that includes the pads 312 (e.g., a bottom surface).

Additionally, a second layer (e.g., a top layer, in one perspective) of the multilayer package substrate 300 includes ports 330. The ports 330 are configured to be coupled to a die, such as the die 112 of FIG. 1. A first output port 334 of the ports 330 is coupled to a second node 338 of the first spiral inductor 304 with a via. A second output port 342 is coupled to a second node 346 of the second spiral inductor 308 with a via. In some examples, the first output port 334 and the second output port 342 are coupled together (e.g., within the die). Accordingly, in some examples, the first output port 334 and the second output port 342 are employable to implement the first port 132 of FIG. 1. Furthermore, a first electrical path extending from the first pad 314, through the first spiral inductor 304 and to the first output port 334 is established. The first output port 334 is configured to be coupled to a first input port of the die. Similarly, a second electrical path extending from the second pad 322, through the second spiral inductor 308 and to the second output port 342 is also established. Accordingly, a combination of the first spiral inductor 304 and the second spiral inductor 308 are collectively employable to implement the planar inductor 162 for the passive filter 150 of FIG. 1. The second output port 342 is configured to be coupled to a second input port of the die.

The first spiral inductor 304 and the second spiral inductor 308 are formed on a layer spaced apart from the layer that includes the pads 312 and the ports 330. Stated differently, the first spiral inductor 304 and the second spiral inductor 308 are formed on an interior layer of the multilayer package substrate 300.

Further, in the example illustrated, the multilayer package substrate 300 includes a capacitor 350. In the example illustrated, the capacitor 350 is proximal to the first spiral inductor 304. In other examples, the capacitor 350 is proximal to the second spiral inductor 308. In still other examples, there are two capacitors, such that a capacitor is proximal to both the first spiral inductor 304 and the second spiral inductor 308.

The capacitor 350 is formed with a first plate 354 (e.g., a bottom plate, viewable in FIG. 3B) and a second plate 358 (e.g., a top plate, viewable in FIG. 3A). In some examples, a third plate situated under the second plate 358 is included to provide two capacitors. The first plate 354 and the second plate 358 are formed on separate layers of the multilayer package substrate 300, and are separated, for example, by empty space (e.g., air) or a dielectric. In some such examples, the first plate 354 is formed on a same layer as the first spiral inductor 304 and the second spiral inductor 308. Additionally, in some examples, the first output port 334 is coupled to the second plate 358 and the first plate 354 is coupled to an electrically neutral node. Accordingly, in some examples, the capacitor 350 is employable to implement the capacitor 170 of FIG. 1. Thus, in some such examples, taken together, the first spiral inductor 304, the second spiral inductor 308 and the capacitor 350 operate in concert to provide a passive filter, such as the passive filter 150 of FIG. 1.

In other examples, instead of the capacitor 350 implemented with multiple plates, the multilayer package substrate 300 includes an SMT capacitor (or multiple SMT capacitors), such as the first capacitor 232 and/or the second capacitor 236 of FIGS. 2A-2C.

In some examples, the first spiral inductor 304 and the second spiral inductor 308 have a combined inductance of about 100-250 nH, such as about 182.2 nH in one example. Additionally, the first spiral inductor 304 and the second spiral inductor 308 have a parasitic resistance of about 182.2 mΩ. Furthermore, in such a situation, the capacitor 350 has a capacitance of about 0.1-0.25 pF, such as about 0.193 pF in one example. Moreover, the first spiral inductor 304 and the second spiral inductor 308 have a quality factor (Q) at 10 MHz of about 86.9. As compared to the multilayer package substrate 200 of FIGS. 2A-2C, including two inductors, namely the first spiral inductor 304 and the second spiral inductor 308, instead of the (single) spiral inductor 204 of FIGS. 2A-2C, provides a greater Q factor and lower parasitic resistance at a cost of having a lower inductance. Thus, the multilayer package substrate 200 or the multilayer package substrate 300 are selectable depending on the particular needs of a corresponding circuit.

By employment of the multilayer package substrate 300, two precise inductors, namely the first spiral inductor 304 and the second spiral inductor 308 are provided in a relatively small footprint, namely the footprint of the corresponding semiconductor device (e.g., the semiconductor device 100 of FIG. 1). Thus, the first spiral inductor 304, the second spiral inductor 308 and the capacitor 350 are employable in a passive filter (e.g., the passive filter 150 of FIG. 1), such as in a second section filter of a two section input filter for a power converter.

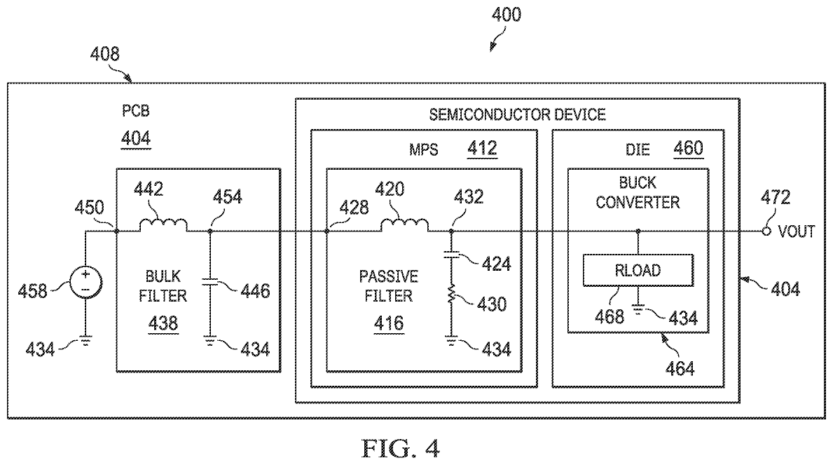

FIG. 4 illustrates an example of a circuit diagram 400 that implements a semiconductor device 404, such as the semiconductor device 100 of FIG. 1. The semiconductor device 404 is mounted on a PCB 408. Moreover, for purposes of simplification of explanation, some components, such as a load (e.g., the load 198 of FIG. 1) have been omitted.

The semiconductor device 404 includes a multilayer package substrate 412 that includes a passive filter 416. In a first example (hereinafter, “the first example”) the multilayer package substrate 412 is implemented with the multilayer package substrate 200 of FIGS. 2A-2C. In a second example, (hereinafter, “the second example”), the multilayer package substrate 412 is implemented with the multilayer package substrate 300 of FIGS. 3A-3C. The multilayer package substrate 412 includes a passive filter 416. The passive filter 416 is employable to implement the passive filter 150 of FIG. 1. The passive filter 416 includes an inductor 420 and a capacitor 424.

In the first example, the inductor 420 is implemented with the spiral inductor 204 of FIGS. 2A-2C. In the second example, the inductor 420 is implemented with a combination of the first spiral inductor 304 and the second spiral inductor 308 of FIGS. 3A-3C. In the first example and the second example, the capacitor 424 is implemented with the first capacitor 232 and/or the second capacitor 236 of FIGS. 2A-2C or the capacitor 350 of FIGS. 3A-3C. The passive filter 416 also includes a resistor 430 that is representative of a parasitic resistance of the capacitor 424.

The passive filter 416 includes an input node 428 and an output node 432. The inductor 420 is coupled to the input node 428 and the output node 432. The capacitor 424 is coupled to the output node 432 and to the resistor 430. Moreover, the resistor 430 is also coupled to an electrically neutral node 434 (e.g., ground or virtual ground).

The input node 428 of the passive filter 416 is coupled to a bulk filter 438 mounted on the PCB 408. In the example illustrated, the bulk filter 438 is a passive filter, but in other examples, the bulk filter 438 is an active filter. The bulk filter 438 includes an inductor 442 and a capacitor 446. The bulk filter 438 includes an input node 450 and an output node 454. The inductor 442 is a planar inductor coupled to the input node 450 and the output node 454 of the bulk filter 438. The capacitor 446 is coupled to the output node 454 and to the electrically neutral node 192. Moreover, a positive terminal of a voltage source 458 is coupled to the input node 450 of the bulk filter 438, and a negative terminal of the voltage source 458 is coupled to the electrically neutral node 192. Further, the output node 454 of the bulk filter 438 is coupled to the input node 428 of the passive filter 416 of the semiconductor device 404.

A die 460 of the semiconductor device 404 is mounted on the multilayer package substrate 412. The die 460 includes a buck converter 464. The buck converter 464 is schematically represented with a resistive load 468 (labeled “RLOAD”). The output node 432 of the passive filter 416 of the semiconductor device 404 is coupled to the resistive load 468. Additionally, the resistive load 468 is also coupled to the electrically neutral node 434. An output node 472 of the buck converter 464 provides an output voltage, VOUT.

As noted, in the first example, the inductor 420 implements the spiral inductor 204 of FIGS. 2A-2C. Accordingly, in the first example, the inductor 420 has an inductance of 330 nH, with a parasitic resistance of 1200 mΩ. Conversely, in the second example, the inductor 420 implements the first spiral inductor 304 and the second spiral inductor 308 of FIGS. 2A-2C. Thus, in the second example, the inductor 420 has an inductance of 33 nH and a parasitic resistance of 190 mΩ. In both the first and second examples, it is presumed that the inductor 442 has an inductance of 330 microhenries (μH) and the capacitor 446 has a capacitance of 470 microfarads (μF). Further, in both the first and second examples, it is presumed that the resistive load 468 has a resistance of 3 Ohms (Ω). Further still, in the first and second examples, the capacitor 424 has a capacitance of 2.2 μF and the resistor 430 has a resistance of 10 mΩ.

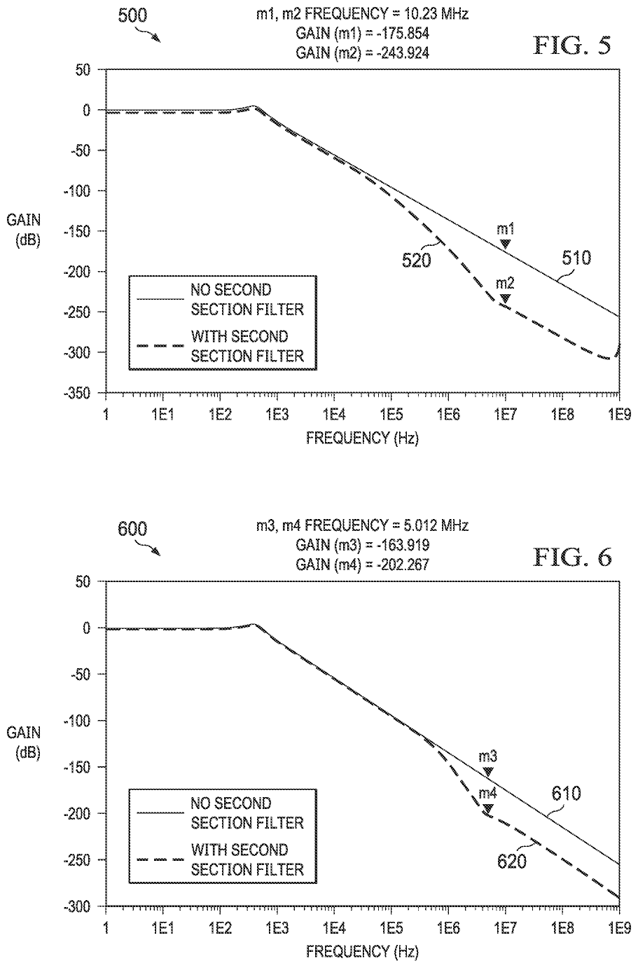

In operation, the bulk filter 438 operates as a first section filter of a two section input filter for the buck converter 464, and the passive filter 416 of the multilayer package substrate 412 operates as a second section filter of the two section input filter for the buck converter 464. Inclusion of a second section filter improves operational performance of the buck converter 464, which includes improved frequency rejection performance of the buck converter 464. FIGS. 5 and 6 illustrate the improved performance of the first example and the second example, respectively.

More particularly, FIG. 5 illustrates a graph 500 that plots an output voltage, VOUT of the circuit diagram 400 of FIG. 4 in the first example (setting the inductor 420 to an inductance of 303 nH with a parasitic resistance of 1200 mΩ). The graph 500 plots a gain of the output voltage, VOUT, in decibels (dB) as a function of frequency, in hertz (Hz)). The graph 500 includes a first plot 510 that omits the second section filter, namely the passive filter 416, and a second plot 520 that includes the second section filter. For purposes of illustration of contrast, a point, labeled “m1” of the first plot 510 and a point, labeled “m2” of the second plot 520 are compared with a frequency of 10.23 MHz. At point m1, (without the second section filter) there is a gain of −175.854 dB, and at point m2 (with the second section filter), there is a gain of −243.924 dB. Thus, including the second section filter in the first example improves frequency rejection performance by about 68.07 dB.

FIG. 6 illustrates a graph 600 that plots an output, VOUT of the circuit diagram 400 of FIG. 4 in the second example (setting the inductor 420 to an inductance of 33 nH with a parasitic resistance of 190 mΩ). The graph 600 plots a gain of the output, VOUT, in decibels (dB) as a function of frequency, in hertz (Hz)). The graph 600 includes a first plot 610 that omits the second section filter, namely the passive filter 416, and a second plot 620 that includes the second section filter. For purposes of illustration of contrast, a point labeled “m3” of the first plot 610 and a point, labeled “m4” of the second plot 620 are compared with a frequency of 10.23 MHz. At point m3, (without the second section filter) there is a gain of −163.919 dB, and at point m3 (with the second section filter), there is a gain of −202.267 dB. Thus, including the second section filter in the first example improves frequency rejection performance by about 38.348 dB.

Referring back to FIG. 4, as illustrated by the graphs 500 and 600 of FIGS. 5 and 6, inclusion of the passive filter 416 in the semiconductor device 404 improves performance of the circuit diagram 400. Moreover, as illustrated in FIGS. 2A-2C and 3A-3C, the passive filter 416 is integrated with the multilayer package substrate 412, such that the passive filter 416 is included as a second section filter without an increase in cost to the semiconductor device 404.

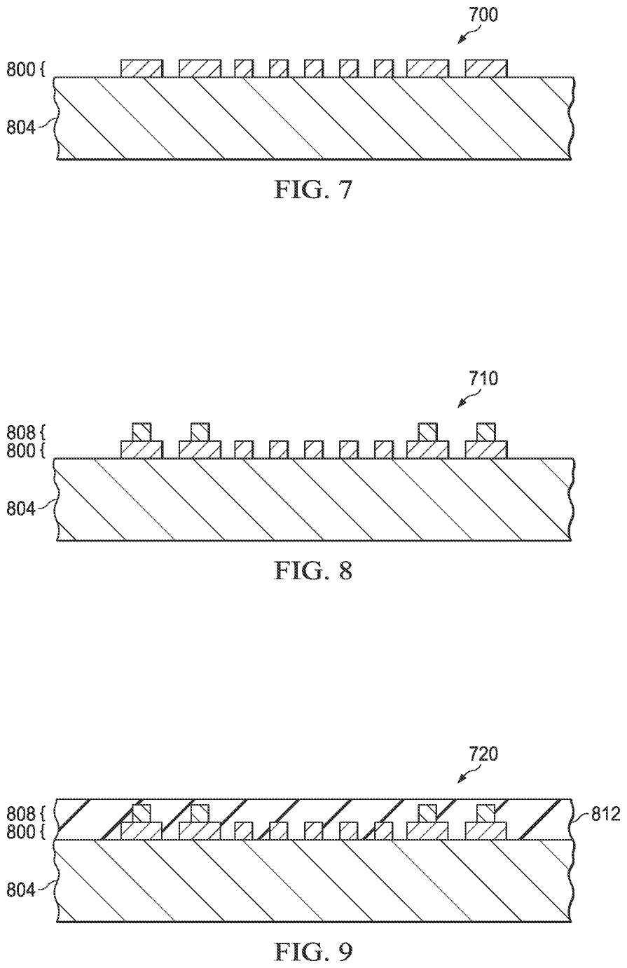

FIGS. 7-15 illustrate stages of a method for fabricating a multilayer package substrate, such as the multilayer package substrate 108 of FIG. 1, the multilayer package substrate 200 of FIGS. 2A-2C, the multilayer package substrate 300 of FIG. 3A-3C or the multilayer package substrate 412 of FIG. 4. The method of FIGS. 7-15 illustrates how multiple layers (four layers) of material are employable to provide the multilayer package substrate. Moreover, a similar method can be employed to provide other types of connector assemblies.

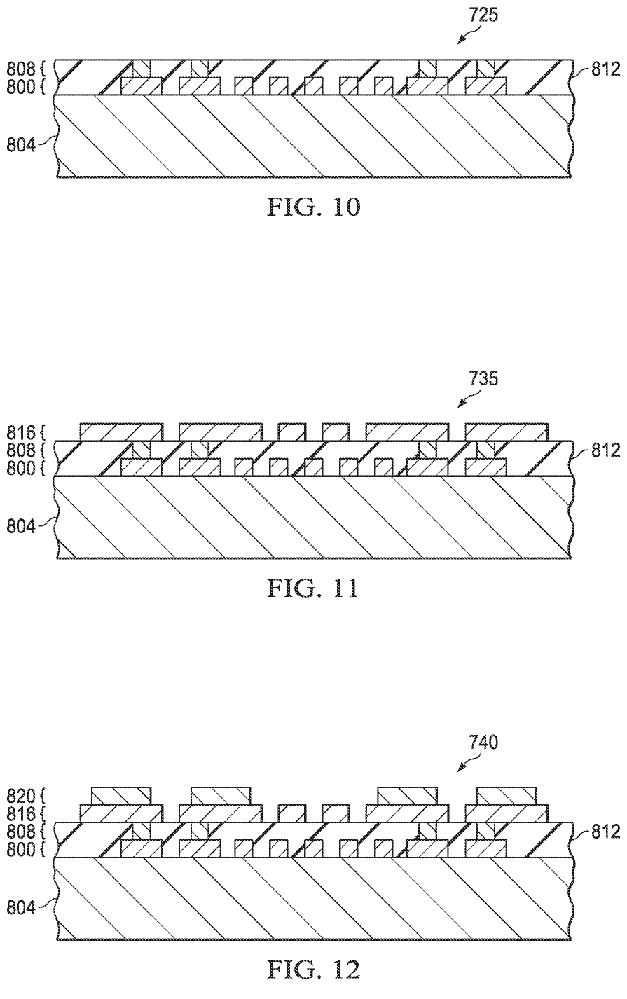

As illustrated in FIG. 7, at 700, in a first stage, a first metal plating pattern 800 is plated on a metal carrier 804 to form a first layer of the multilayer package substrate. As illustrated in FIG. 8, in a second stage, at 710, pillars 808 (e.g., copper pillars or pillars formed of other metal) are plated on the first metal plating pattern 800. As illustrated in FIG. 9, at 720, in a third stage, a first dielectric layer 812 is applied in a compressed molding operation to the pillars 808 and to the first metal plating pattern 800. As illustrated in FIG. 10, in a fourth stage, at 725, a portion of the first dielectric layer 812 is removed in a grinding operation, such that regions of the pillars 808 are exposed, and a second layer of the multilayer package substrate is formed.

In some examples, the multilayer package substrate is completed after forming two layers. In this situation, the metal carrier 804 is removed. Additionally, in some examples, the multilayer package substrate is formed with four layers. In this situation, the method continues to a fifth stage.

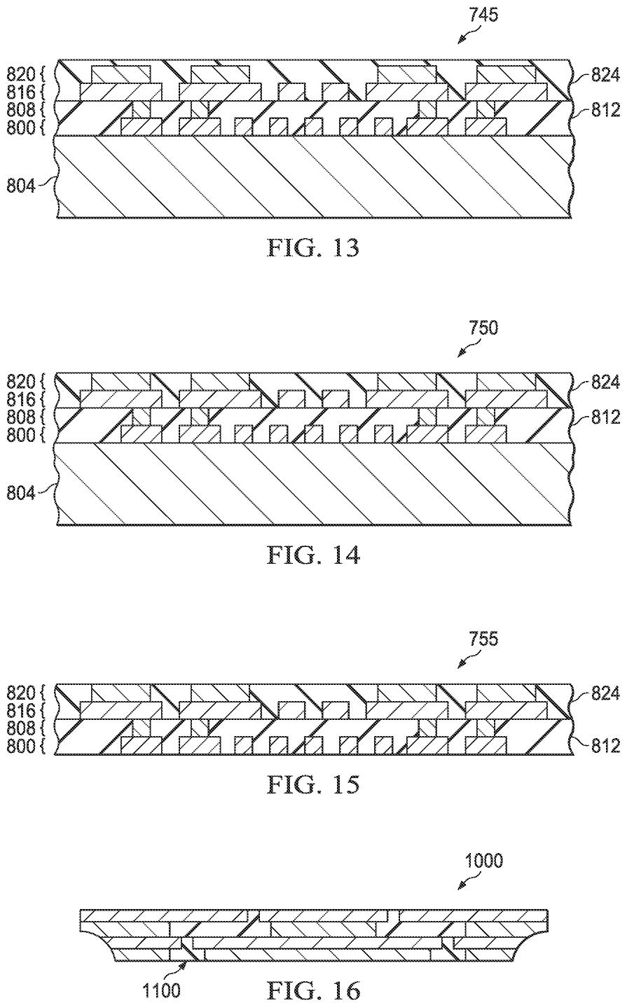

More particularly, as illustrated in FIG. 11, in the fifth stage, at 735, a second metal plating pattern 816 is plated on the first dielectric layer 812 of the second layer of the multilayer package substrate to form a third layer of the multilayer package substrate. As illustrated in FIG. 12, in a sixth stage, at 740 pillars 820 (e.g., copper pillars or pillars formed of other metal) are applied to the second metal plating pattern 816. As illustrated in FIG. 13, in a seventh stage, at 745 a second dielectric layer 824 is applied in a compressed molding operation to the pillars 820 and to the second metal plating pattern 816. As illustrated in FIG. 14, in an eight stage, at 750, a portion of the second dielectric layer 824 is removed in a grinding operation, such that regions of the pillars 820 are exposed, and a fourth layer of the multilayer package substrate is formed. As illustrated in FIG. 15, in a ninth stage, at 755, the metal carrier 804 is removed in a de-carrier operation. The de-carrier operation executed at 755 exposes a region of the first metal plating pattern 800. In examples where a two layer multilayer package substrate is implemented, the operations at 755 are executed and the operations of 735, 740, 745 and 750 of FIGS. 11-14 are omitted.

As illustrated in FIGS. 7-15, by implementing the method, the resultant four layers of the multilayer package substrate are employable to provide relatively complex electrical paths. In particular, as illustrated in FIGS. 7-15, the first dielectric layer 812 and the second dielectric layer 824 are formed (pre-molded) prior to mounting a die on the multilayer package substrate. Such a pre-molding operation distributes dielectric throughout the multilayer package substrate and enables the complexities of circuit components described herein. For instance, in one example, a first portion of the first metal plating pattern 800 and the second metal plating pattern 816 are employable to form an electrical path, such as the electrical path between the first pad 214 and the second pad 216, through the spiral inductor 204 and to the output port 224 of FIGS. 2A-2C. In another example, the first portion of the first metal plating pattern 800 and the second metal plating pattern 816 are employable to form an electrical path, such as the electrical path between the first pad 314, through the first spiral inductor 304 and to the first output port 334 of FIGS. 3A-3C. Similarly, a second portion of the first metal plating pattern 800 and the second metal plating pattern 816 are employable to form a second electrical path, such as the electrical path from the second pad 322, through the second spiral inductor 308 and to the second output port 342 of FIGS. 3A-3C.

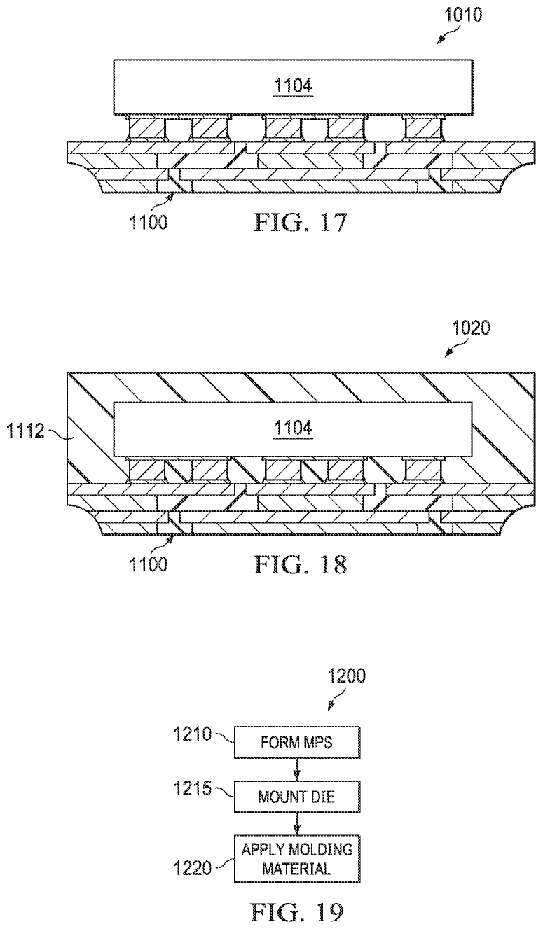

FIG. 16-18 illustrate stages of a method for packaging a semiconductor device (e.g., an IC chip). The semiconductor device formed by the method of FIGS. 16-18 is employable to implement the semiconductor device 100 of FIG. 1 and/or the semiconductor device 404 of FIG. 4. As illustrated in FIG. 16, in a first stage, at 1000, a multilayer package substrate 1100 is provided. As one example, the multilayer package substrate 1100 is formed with the method illustrated in FIGS. 7-15. As illustrated in FIG. 17, in a second stage, at 1010 a die 1104 is mounted on (adhered to) the multilayer package substrate 1100 in a soldering operation. The die includes a power converter module, such as the buck converter 464 of FIG. 4. As illustrated in FIG. 18, in a third stage, at 1020, a molding material 1112 is applied to the die 1104 and the multilayer package substrate 1100 in a packaging operation to form the semiconductor device.

As demonstrated in FIGS. 16-18, in the method illustrated, the multilayer package substrate 1100 is pre-molded with dielectric for the die 1104. Accordingly, the method enable complex structures, such as the spiral inductor 204 of FIGS. 2A-2C or the first spiral inductor 304 and the second spiral inductor 308 of FIGS. 3A-3C to be implemented within the confines of the multilayer package substrate 1100.

FIG. 19 illustrates a flowchart of an example method 1200 for forming a semiconductor device (e.g., an IC package). The method 1200 could be employed for example, to form the semiconductor device 100 of FIG. 1 and/or the semiconductor device 404 of FIG. 4. At 1210, a multilayer package substrate (e.g., the multilayer package substrate 108 of FIG. 1, the multilayer package substrate 200 of FIGS. 2A-2C or the multilayer package substrate 300 of FIGS. 3A-3C) or other type of connector assembly can be formed. The multilayer package substrate is formed, for example, with the method illustrated in FIGS. 7-15. The multilayer package substrate can include a layer a that includes pads, and a layer that includes a spiral inductor for a passive filter, such as the spiral inductor 204 of FIGS. 2A-2C or the first spiral inductor 304 and the second spiral inductor 308 of FIGS. 3A-3C. Additionally, the multilayer package substrate includes a capacitor (or multiple capacitors) for the passive filter in some examples, such as the capacitor 350 of FIGS. 3A-3C. The layers of the multilayer package substrate form a first electrical path between a first pad of pads of the multilayer package substrate, through the inductor and to an output port of the multilayer package substrate. In some examples, the spiral inductor is coupled to a first pad of the pads of the multilayer package substrate with a first via of the multilayer package substrate and to an output port of the multilayer package substrate with a second via of the multilayer package substrate. Additionally, the spiral inductor extends in parallel to a surface of the multilayer package substrate.

Further, in some examples, forming the multilayer package substrate at 1210 includes mounting a SMT capacitor of the passive filter on the multilayer package substrate. In some examples, the SMT capacitor is implemented with the first capacitor 232 and/or the second capacitor 236 of FIGS. 2A-2C.

At 1215, a die (e.g., the die 112 of FIG. 1) is mounted to the multilayer package substrate, the die includes a power converter module (e.g., the power converter module 116 of FIG. 1). The die includes an input port and an output port. The die is mounted such that the input port of the die is coupled to the output port of the multilayer package substrate and the output port of the die is coupled to a second pad of the pads of the multilayer package substrate. At 1220, molding material is applied to the die and the multilayer package substrate to form the semiconductor device.

Modifications are possible in the described embodiments, and other embodiments are possible, within the scope of the claims.

What is claimed is:

1. A semiconductor device comprising:
a die comprising an input port and an output port; and
a multilayer package substrate comprising:
pads on a surface of the multilayer package substrate configured to be coupled to circuit components of a printed circuit board (PCB); and
a passive filter comprising an input port and an output port, and a planar inductor coupled to a given pad of the pads of the multilayer package substrate with a first via of the multilayer package substrate and to the input port of the die with a second via of the multilayer package substrate, wherein the planar inductor extends parallel to the surface of the multilayer package substrate.

2. The semiconductor device of claim 1, wherein the planar inductor is a spiral inductor formed on an interior layer of the multilayer package substrate.

3. The semiconductor device of claim 2, wherein the passive filter further comprises a capacitor coupled to the input port of the die and to another pad of the pads of the multilayer package substrate.

4. The semiconductor device of claim 3, wherein the capacitor is formed with plates formed on spaced apart layers of the multilayer package substrate.

5. The semiconductor device of claim 3, wherein the capacitor is a surface mount technology (SMT) capacitor.

6. The semiconductor device of claim 1, wherein the planar inductor is a first spiral inductor, and the input port of the die is a first input port, the passive filter comprising a second spiral inductor coupled to the second input port of the die with a third via and to another pad of the pads of the multilayer package substrate with a fourth via.

7. The semiconductor device (of claim 6, wherein the first spiral inductor and the second spiral inductor have about equal inductance.

8. The semiconductor device of claim 7, wherein the first spiral inductor and the second spiral inductor are spaced apart.

9. The semiconductor device of claim 8, wherein the first spiral inductor and the second spiral inductor have a combined inductance of at least 20 nanohenries.

10. The semiconductor device of claim 1, wherein the planar inductor is coupled to another pad of the multilayer package substrate with a third via.

11. The semiconductor device of claim 10, wherein the planar inductor has an inductance of at least 200 nanohenries.

12. The semiconductor device of claim 1, wherein the die comprises a power converter module, and the output port of the die is configured to be coupled to a load mounted on the PCB.

13. The semiconductor device of claim 12, wherein the power converter module is a buck converter.

14. The semiconductor device of claim 13, wherein the passive filter is configured to be coupled to a bulk filter mounted of the PCB, whereby the bulk filter is a first section filter of a two section input filter for the power converter module and the passive filter is a second section filter of the two section input filter for the power converter module.

15. A method for forming a semiconductor device, the method comprising:
forming a multilayer package substrate that include pads on a surface for connecting the semiconductor device to a printed circuit board, and a passive filter comprising a planar inductor coupled to a first pad of the pads of the multilayer package substrate with a first via and to an output port of the multilayer package substrate with a second via, wherein the planar inductor extends in parallel to the surface of the multilayer package substrate; and
mounting a die to the multilayer package substrate, the die comprising an input port coupled to the output port of the multilayer package substrate and an output port coupled to a second pad of the pads of the multilayer package substrate.

16. The method of claim 15, wherein the forming of the multilayer package substrate further comprises:
forming a first metal plating pattern to form a first layer of the multilayer package substrate; and
applying a dielectric layer to the first metal plating pattern to form a second layer of the multilayer package substrate.

17. The method of claim 16, wherein the planar inductor is a spiral inductor, and the second layer includes the spiral inductor of the passive filter.

18. The method of claim 16, wherein the spiral inductor is a first spiral inductor, and the second layer includes the first spiral inductor and a second spiral inductor of the passive filter.

19. The method of claim 15, wherein the forming of the multilayer package substrate further comprises mounting a surface mount technology (SMT) capacitor of the passive filter on the multilayer package substrate.

20. The method of claim 15, further comprising applying a molding material to the die adhered to the multilayer package substrate to form the semiconductor device.

21. An apparatus, comprising:
a printed circuit board (PCB);
a die comprising an input port and an output port; and
a multilayer package substrate comprising:
pads on a surface of the multilayer package substrate coupled to circuit components of a printed circuit board (PCB); and
a passive filter comprising an input port and an output port, and a planar inductor coupled to a given pad of the pads of the multilayer package substrate with a first via of the multilayer package substrate and to the input port of the die with a second via of the multilayer package substrate, wherein the planar inductor extends parallel to the surface of the multilayer package substrate.

22. A method for making an apparatus, the method comprising:
providing a printed circuit board (PCB);
forming a multilayer package substrate;
connecting pads on the multilayer package substrate to the printed circuit board (PCB), and a passive filter comprising a planar inductor coupled to a first pad of the pads of the multilayer package substrate with a first via and to an output port of the multilayer package substrate with a second via, wherein the planar inductor extends in parallel to the surface of the multilayer package substrate; and
mounting a die to the multilayer package substrate, the die comprising an input port coupled to the output port of the multilayer package substrate and an output port coupled to a second pad of the pads of the multilayer package substrate.
